(19) United States
(12) Patent Application Publication
(10) Pub. No.: US 2019/0198095 A1
(43) Pub. Date: Jun. 27, 2019

(54) MEMORY DEVICE

(71) Applicant: NANYA TECHNOLOGY CORPORATION, New Taipei City (TW)

(72) Inventors: WEI-CHUAN FANG, NEW TAIPEI CITY (TW); CHUN-PEI LIN, TAOYUAN CITY (TW); LIANG-PIN CHOU, TAOYUAN CITY (TW)

(21) Appl. No.: 15/883,716

(22) Filed: Jan. 30, 2018

Related U.S. Application Data
(60) Provisional application No. 62/610,263, filed on Dec. 25, 2017.

(51) Int. Cl. G11C 11/56; G11C 11/40; G11C 11/50; H01L 27/105

(52) U.S. Cl. CPC G11C 11/56; H01L 27/1052; G11C 11/50; G11C 11/40

(57) ABSTRACT

The present disclosure provides a memory device including a first electrode; a second electrode; a transistor, and a nanotube. The transistor includes a first node, a second node and a control node, wherein the second node is electrically coupled to the second electrode, and the control node is configured to generate a channel between the first node and the second node. A first end of the nanotube is electrically coupled to a contact, and a second end of the nanotube is positioned between the first electrode and the second electrode. The second end electrically connects the first electrode to form a non-volatile open state of the memory device, or the second end electrically connects the second electrode to form a non-volatile closed state of the memory device. The non-volatile open state represents a first logic state and the non-volatile closed state represents a second logic state.

### PRIORITY CLAIM AND CROSS-REFERENCE

This application claims priority of U.S. provisional application Ser. No. 62/610,263 filed on Dec. 25, 2017, which is incorporated herein by reference in its entirety.

### TECHNICAL FIELD

The present disclosure relates to a memory device, and more particularly, to a memory device including at least one carbon nanotube.

### DISCUSSION OF THE BACKGROUND

Carbon nanotubes (CNT) are miniature cylindrical carbon elements that have hexagonal graphite molecules attached at the edges. Carbon nanotubes have the potential to be used as semiconductors, potentially replacing silicon in a wide variety of computing devices.

This Discussion of the Background section is provided for background information only. The statements in this Discussion of the Background are not an admission that the subject matter disclosed in this section constitutes prior art to the present disclosure, and no part of this section may be used as an admission that any part of this application, including this Discussion of the Background section, constitutes prior art to the present disclosure.

### SUMMARY

One aspect of the present disclosure provides a memory device comprising a first electrode, a second electrode, a transistor and a nanotube. The transistor comprises a first node, a second node and a control node, wherein the second node is electrically coupled to the second electrode, and the control node is configured to generate a channel between the first node and the second node. A first end of the nanotube is electrically coupled to a contact, and a second end of the nanotube is positioned between the first electrode and the second electrode; wherein the second end electrically connects the first electrode to form a non-volatile open state of the memory device, or the second end electrically connects the second electrode to form a non-volatile closed state of the memory device; wherein the non-volatile open state represents a first logic state and the non-volatile closed state represents a second logic state.

In some embodiments, a first voltage applied to the contact, and the second end of the nanotube is attracted by the second electrode, to which a second voltage is applied, when the memory device is under the non-volatile closed state; wherein the first voltage is substantially different from the second voltage.

In some embodiments, a third voltage applied to the contact, the second end of the nanotube is attracted by the first electrode, to which a fourth voltage is applied, when the memory device is under the non-volatile open state; wherein the third voltage is substantially the same as the fourth voltage.

In some embodiments, the nanotube is a carbon nanotube doped with nitrogen.

In some embodiments, the nitrogen concentration of the carbon nanotube doped with nitrogen is between 2% and 10%.

In some embodiments, the non-volatile open state is formed between the second node and the contact, and the non-volatile closed state is formed between the second node and the contact.

In some embodiments, the control node is activated to generate the channel between the first node and the second node, the non-volatile open state is formed between the first node and the contact, and the non-volatile closed state is formed between the first node and the contact.

Another aspect of the present disclosure provides a memory device comprising a first contact, a second contact, a first nanotube electrically coupled to the first contact, a second nanotube electrically coupled to the second contact, and a transistor. The transistor comprises a first node, a second node and a control node, wherein the second node is electrically coupled to the second contact, and the control node is configured to activate a channel between the first node and the second node. The first nanotube electrically connects the second nanotube to form a non-volatile closed state of the memory device, or electrically disconnects the second nanotube to form a non-volatile open state of the memory device, wherein the non-volatile closed state represents a first logic state and the non-volatile open state represents a second logic state.

In some embodiments, a first voltage applied to the first contact, the first nanotube is attracted by the second nanotube, to which a second voltage is applied when the memory device is under the non-volatile closed state; wherein the first voltage is substantially different from the second voltage.

In some embodiments, a third voltage applied to the first contact, the first nanotube is repelled by the second nanotube, to which a fourth voltage is applied when the memory device is under the non-volatile open state; wherein the third voltage is substantially the same as the fourth voltage.

In some embodiments, the first nanotube and the second nanotube are carbon nanotubes doped with nitrogen.

In some embodiments, the nitrogen concentration of the carbon nanotubes doped with nitrogen is between 2% and 10%.

In some embodiments, the non-volatile open state is formed between the second node and the first contact, and the non-volatile closed state is formed between the second node and the first contact.

In some embodiments, the control node is activated to generate the channel between the first node and the second node, the non-volatile open state is formed between the first node and the first contact, and the non-volatile closed state is formed between the first node and the first contact.

Another aspect of the present disclosure provides a memory device comprising a first contact, a second contact, a transistor and a nanotube. The transistor comprises a first node, a second node and a control node, wherein the second node is electrically coupled to the second contact, and the control node is configured to activate a channel between the first node and the second node. The nanotube electrically connects the first contact and the second contact to form a non-volatile closed state of the memory device, or electrically disconnects the first contact and the second contact to form a non-volatile open state of the memory device, wherein the non-volatile closed state represents a first logic state and the non-volatile open state represents a second logic state.

In some embodiments, a first voltage applied to the first contact and a second voltage is applied to the nanotube, and the nanotube electrically connects the first contact and the second contact when the memory device is under the non-volatile closed state; wherein the first voltage is substantially different from the second voltage.

In some embodiments, a third voltage applied to the first contact, a fourth voltage is applied to the nanotube, and the nanotube electrically disconnects the first contact and the second contact when the memory device is under the non-volatile open state; wherein the third voltage is substantially the same as the fourth voltage.

In some embodiments, the nanotube is carbon nanotubes doped with nitrogen.

In some embodiments, the nitrogen concentration of the carbon nanotube doped with nitrogen is between 2% and 10%.

In some embodiments, the nanotube is electrically coupled to the second contact, the non-volatile open state is formed between the second node and the first contact, and the non-volatile closed state is formed between the second node and the first contact.

In some embodiments, the nanotube is electrically coupled to the second contact, the control node is activated to generate the channel between the first node and the second node, the non-volatile open state is formed between the first node and the first contact, and the non-volatile closed state is formed between the first node and the first contact.

In the present disclosure, when the applied voltage difference between the nanotube and a reference electrode exceeds a threshold voltage difference, the equilibrium position of the switch is changed. The reference electrode includes the second electrode and the first electrode. Once the switch is in contact with the reference electrode, the electrostatic force is removed by a reduction of the voltage difference between the switch and the reference electrode to 0 volts. Even if the electrical power is lost, the switch still maintains contact with the first electrode or with the second electrode, and thus stores a bit of data in a non-volatile manner. Another advantage is that the switch does not consume any electrical power if the switch does not change its state.

In contrast, a DRAM stores each bit of data in a separate capacitor within an integrated circuit. The electric charge in the capacitors slowly leaks, so without any intervention the data in the DRAM would soon be lost, and therefore the DRAM cannot store data in a non-volatile manner. Another disadvantage of the DRAM is that the DRAM still consumes electrical power even if the DRAM does not change the data.

The foregoing has outlined rather broadly the features and technical advantages of the present disclosure in order that the detailed description of the disclosure that follows may be better understood. Additional features and advantages of the disclosure are described hereinafter, and form the subject of the claims of the disclosure. It should be appreciated by those skilled in the art that the conception and specific embodiment disclosed may be readily utilized as a basis for modifying or designing other elements or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures. and:

FIG. 1 is a schematic diagram of a DRAM cell;

FIG. 2 is a schematic diagram of an electronic switch, in accordance with an exemplary embodiment of the present disclosure;

FIG. 3 is a schematic diagram of a non-volatile memory cell, in accordance with an exemplary embodiment of the present disclosure;

FIG. 4 is an operation diagram of a non-volatile memory cell, in accordance with an exemplary embodiment of the present disclosure;

FIG. 5 is another operation diagram of the non-volatile memory cell, in accordance with an exemplary embodiment of the present disclosure;

FIG. 6 is a diagram of voltage waveforms applied to the terminals to change the state of the switch, in accordance with an exemplary embodiment of the present disclosure;

FIG. 7 is another diagram of voltage waveforms applied to the terminals to change the state of the switch;

FIG. 8 is a schematic circuit diagram of another non-volatile memory cell, in accordance with an exemplary embodiment of the present disclosure;

FIG. 9 is an operation diagram of the non-volatile memory cell, in accordance with an exemplary embodiment of the present disclosure;

FIG. 10 is another operation diagram of the non-volatile memory cell, in accordance with an exemplary embodiment of the present disclosure;

FIG. 11 is a schematic circuit diagram of a non-volatile random access memory, in accordance with an exemplary embodiment of the present disclosure;

FIG. 12 is a diagram of voltage waveforms applied to a word line, a bit line, a switch line and an open line to change the state of the switch, in accordance with an exemplary embodiment of the present disclosure;

FIG. 13 is another diagram of voltage waveforms applied to the word line, another bit line, another switch line and another open line to change the state of the switch, in accordance with an exemplary embodiment of the present disclosure;

FIG. 14 is an operation diagram of a non-volatile memory cell, in accordance with an exemplary embodiment of the present disclosure;

FIG. 15 is a diagram of voltage waveforms applied to the terminals for a writing 1 operation, in accordance with an exemplary embodiment of the present disclosure;

FIG. 16 is another operation diagram of a non-volatile memory cell, in accordance with an exemplary embodiment of the present disclosure;

FIG. 17 is a diagram of voltage waveforms applied to the terminals for a writing 0 operation, in accordance with an exemplary embodiment of the present disclosure;

FIG. 18 is an operation diagram of a non-volatile memory cell, in accordance with an exemplary embodiment of the present disclosure;

FIG. 19 is a diagram of voltage waveforms applied to the word line, the bit line and the open line for a writing 1 operation, in accordance with an exemplary embodiment of the present disclosure;

FIG. 20 is an operation diagram of the non-volatile memory cell, in accordance with an exemplary embodiment of the present disclosure;

FIG. 21 is a diagram of voltage waveforms applied to the word line, the bit line and the open line for a writing 0 operation, in accordance with an exemplary embodiment of the present disclosure;

FIG. 22 is another diagram of voltage waveforms applied to the word line and the open line within the reading interval for reading the voltage of the bit line, in accordance with an exemplary embodiment of the present disclosure; and

FIG. 23 is another diagram of voltage waveforms applied to the word line and the open line within the reading interval for reading the voltage of the bit line, in accordance with an exemplary embodiment of the present disclosure.

FIG. 24 is an operation diagram of another non-volatile memory cell, in accordance with an exemplary embodiment of the present disclosure;

FIG. 25 is a diagram of voltage waveforms applied to the terminals for a writing 1 operation, in accordance with an exemplary embodiment of the present disclosure;

FIG. 26 is another operation diagram of a non-volatile memory cell, in accordance with an exemplary embodiment of the present disclosure;

FIG. 27 is a diagram of voltage waveforms applied to the terminals for a writing 0 operation, in accordance with an exemplary embodiment of the present disclosure:

FIG. 28 is an operation diagram of a non-volatile memory cell, in accordance with an exemplary embodiment of the present disclosure;

FIG. 29 is a diagram of voltage waveforms applied to the word line, the bit line and the open line for a writing 1 operation, in accordance with an exemplary embodiment of the present disclosure;

FIG. 30 is an operation diagram of the non-volatile memory cell, in accordance with an exemplary embodiment of the present disclosure;

FIG. 31 is a diagram of voltage waveforms applied to the word line, the bit line and the open line for a writing 0 operation, in accordance with an exemplary embodiment of the present disclosure;

FIG. 32 is another diagram of voltage waveforms applied to the word line and the open line within the reading interval for reading the voltage of the bit line, in accordance with an exemplary embodiment of the present disclosure; and

FIG. 33 is another diagram of voltage waveforms applied to the word line and the open line within the reading interval for reading the voltage of the bit line, in accordance with an exemplary embodiment of the present disclosure.

### DETAILED DESCRIPTION

Embodiments, or examples, of the disclosure illustrated in the drawings are now described using specific language. It shall be understood that no limitation of the scope of the disclosure is thereby intended. Any alteration or modification to the described embodiments, and any further applications of principles described in this document, are to be considered as normally occurring to one of ordinary skill in the art to which the disclosure relates. Reference numerals may be repeated throughout the embodiments, but this does not necessarily require that feature(s) of one embodiment apply to another embodiment, even if they share the same reference numeral.

It shall be understood that when an element is referred to as being “connected to” or “coupled with” another element, it may be directly connected to or coupled to the other element, or intervening elements may be present.

It shall be understood that, although the terms high, low, third, etc. may be used herein to describe various elements, components, regions, layers or sections, these elements, components, regions, layers or sections should not be limited by these terms. Rather, these terms are merely used to distinguish one element, component, region, layer or section from another region, layer or section. Thus, a high element, component, region, layer or section discussed below could be termed a low element, component, region, layer or section without departing from the teachings of the present inventive concept.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It shall be further understood that the terms “comprises” and “comprising,” when used in this specification, specify the presence of stated features, integers, steps, operations, elements, or components, but do not preclude the presence or addition of one or more other features, integers, steps, operations, elements, components, or groups thereof.

Currently, existing memory products include Read Only Memory (ROM), Programmable Read Only Memory (PROM), Electrically Programmable Memory (EPROM), Electrically Erasable Programmable Read Only Memory (EEPROM), Flash, Dynamic Random Access Memory (DRAM) and Static Random Access Memory (SRAM). Important characteristics for a memory device in an electronic device are low cost, non-volatility, high density, low power consumption, and high operation speed.

ROM is relatively cheap but cannot be reprogrammed, whereas PROM can be electrically programmed with only a single write cycle. EPROM has read cycles that are fast relative to ROM and PROM read cycles, but has relatively long erase times and limited reliability. EEPROM is cheap and has low power consumption, but has long write cycles and low relative operation speed in comparison with DRAM or SRAM. Flash also has a finite number of read/write cycles leading to low long-term reliability. ROM, PROM, EPROM and EEPROM are all non-volatile, meaning that even if electrical power is removed the memory still retains the information stored in the memory cells.

Dynamic random-access memory (DRAM) is used in most computing devices and electrical mobile devices. DRAM is a type of random access memory that stores each bit of data in a separate capacitor. The capacitor can be either charged or discharged; the two states (charged or discharged) are used to represent the two values (0 or 1) of a bit. The electric charge in the capacitors tends to leak away, so that without refreshing, the data in the capacitors is soon lost. In order to prevent such data loss, DRAM requires an external memory refresh circuit that periodically refreshes the data stored in the capacitors, restoring them to their original charge. Due to the limitation of the need to be refreshed, DRAM is a volatile memory, and therefore DRAM cannot maintain the data if the electric power is removed.

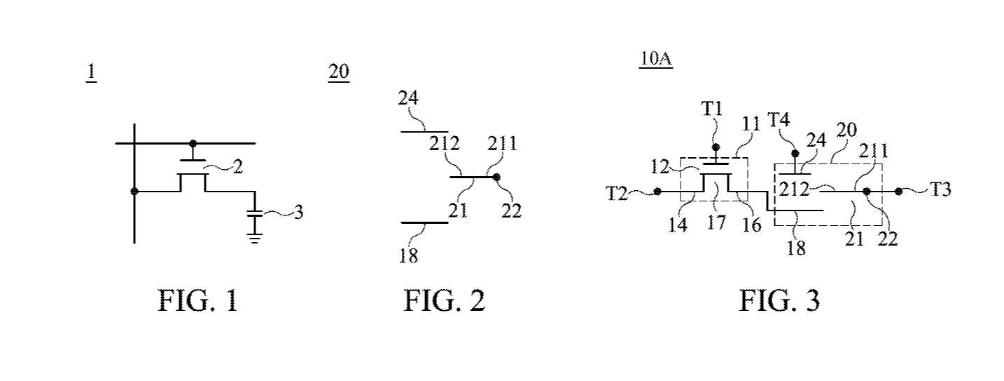

FIG. 1 is a schematic diagram of a DRAM cell 1. Referring to FIG. 1, a DRAM cell 1 includes a metal-oxide-semiconductor field-effect transistor (MOSFET) 2 and a capacitor 3. The capacitor 3 is either charged or discharged; the two states (charged or discharged) are used to represent the two values of a bit, conventionally called 0 and 1. The electric charge in the capacitors slowly leaks away, so that without refreshing the data stored in the DRAM cell 1 would soon be lost. Therefore, the DRAM is not a non-volatile storage device. Another disadvantage of the DRAM is the operation time, because capacitors of the DRAM require a long time to charge. These disadvantages indeed restrict the application of the DRAM.

An N-doped carbon nanotube (a carbon nanotube doped with nitrogen) is a type of a nanotube with uniform dispersion. The N-doped carbon nanotube is generated using a carbon nanotube that is doped with nitrogen. The N-doped carbon nanotube has uniform dispersion and has high electrical conductivity. These characteristics make the N-doped carbon nanotube suitable to implement the switch for serving as a non-volatile memory cell.

The disclosure discloses a switch including a nanotube and a memory device using the switch to serve as the non-volatile memory cell. Different voltages are applied to the nanotube to create an electrostatic force that causes the nanotube to physically and electrically contact a first electrode or a second electrode; each physical state (contacting a first electrode or a second electrode) represents an electrical state, allowing the mechanism to be used to represent a value of a bit. Even if the electrical power is lost, the nanotube maintains its physical state (i.e., contacting the first electrode or the second electrode), and thereby maintains the value of the bit in a non-volatile manner, and the memory cell thus comprised is a non-volatile memory cell.

The following is a process for manufacturing the N-doped carbon nanotube. The N-doped carbon nanotube is grown by microwave chemical-vapor deposition on a silicon substrate using an 8 nm-thick Fe layer as a catalyst and TI as a conduction layer. The conduction layer with thicknesses of 20 nm and 200 nm is deposited on the silicon substrate by electron-beam evaporation. The conduction layer is used not only to prevent the formation of Fe silicides, which impede the formation of the N-doped carbon nanotube, but also to promote the electron transfer between the N-doped carbon nanotube and the silicon substrate. Thermal oxidation in air at 350° C. of the Fe catalyst layer leads to the formation of iron oxide which inhibits the formation of Fe—Ti alloys. Prior to the N-doped carbon nanotube growth, a hydrogen-plasma treatment at 2 KW is employed for 10 minutes for cleaning the silicon substrate and forming fine carbon ion encapsulated metal particles. The N-doped carbon nanotube is grown under conditions of microwave power of 2 KW, gas flow rates of CH4/H2/N2=20/80/80 standard cubic centimeters per minute (SCCM), total pressure of 45 torr, silicon substrate temperature of 1000° C., nitrogen concentration of between 2% and 10%, and deposition time of 10 minutes.

FIG. 2 is a schematic diagram of a switch 20, in accordance with an exemplary embodiment of the present disclosure. Referring to FIG. 2, the switch 20 includes a nanotube 21, a contact 22, a first electrode 24 and a second electrode 18. The nanotube 21 includes a first end 211 and a second end 212: the first end 211 of the nanotube 21 is electrically and physically coupled to the contact 22, and the second end 212 of the nanotube 21 is positioned between the first electrode 24 and the second electrode 18 by an electrostatic force.

FIG. 3 is a schematic diagram of a non-volatile memory cell 10A, in accordance with an exemplary embodiment of the present disclosure. Referring to FIG. 3, the non-volatile memory cell 10A includes a transistor 11, the switch 20, a terminal T1, a terminal T2, a terminal T3 and a terminal T4. The transistor 11 includes a control node 12, a first node 14 and a second node 16; the switch 20 includes the nanotube 21, the contact 22, the first electrode 24 and the second electrode 18. In some embodiments, the transistor 11 is a MOSFET, the first node 14 is a drain of the MOSFET, the second node 16 is a source of the MOSFET, and the control node 12 is a gate of the MOSFET.

The terminal T1 is electrically coupled to the control node 12 of the transistor 11, the terminal T2 is electrically coupled to the first node 14 of the transistor 11, the second node 16 of the transistor 11 is electrically coupled to the second electrode 18, and the terminal T4 is electrically coupled to the first electrode 24. The contact 22 is to electrically coupled to the terminal T3.

The control node 12 is used for creating an electrical field to generate a conductive channel in a channel region 17 transistor 11 between the first node 14 and the second node 16 of the transistor 11. Under certain conditions, the second end 212 of the nanotube 21 is attracted to contact the second electrode 18, which is electrically coupled to the second node 16 of the transistor 11 when the switch 20 is closed (ON); under other conditions, the second end 212 of the nanotube 21 is attracted to contact the first electrode 24, which is electrically coupled to the terminal T4 when the switch 20 is open (OFF). The alternative conditions are described in the next paragraph.

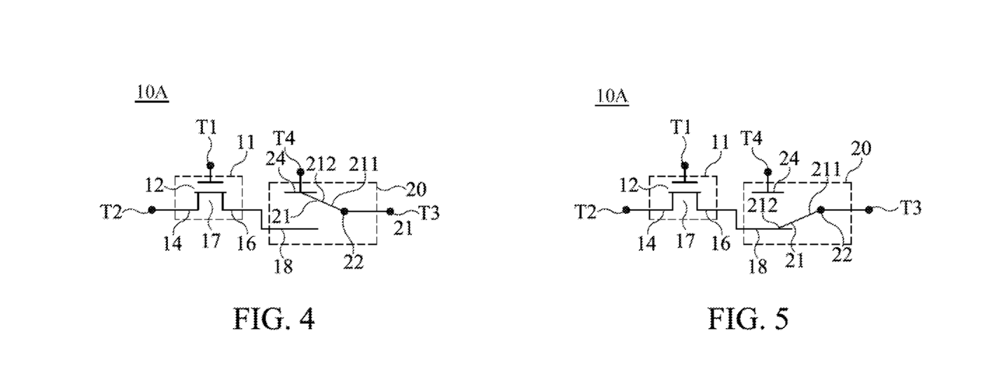

A switching operation is based on an electromechanical operation using an electrostatic force. For applied voltages, an equilibrium position of the switch 20 is defined by the balance of the electrostatic force and the van der Waals force. When the applied voltage difference between the nanotube 21 and a reference electrode exceeds a threshold voltage difference, the switch 20 changes the equilibrium position of the switch 20. The reference electrode includes the second electrode 18 and the first electrode 24. Once the switch 20 is in contact with the reference electrode, the electrostatic force is removed by reducing the voltage difference between the switch 20 and the reference electrode to 0 volts. Even if the electrical power is lost, the switch 20 still maintains contact with the first electrode 24 by the van der Waals force as illustrated in FIG. 4, or still maintains contact with the second electrode 18 by the van der Waals force as illustrated in FIG. 5, and thus stores a bit of data in a non-volatile manner.

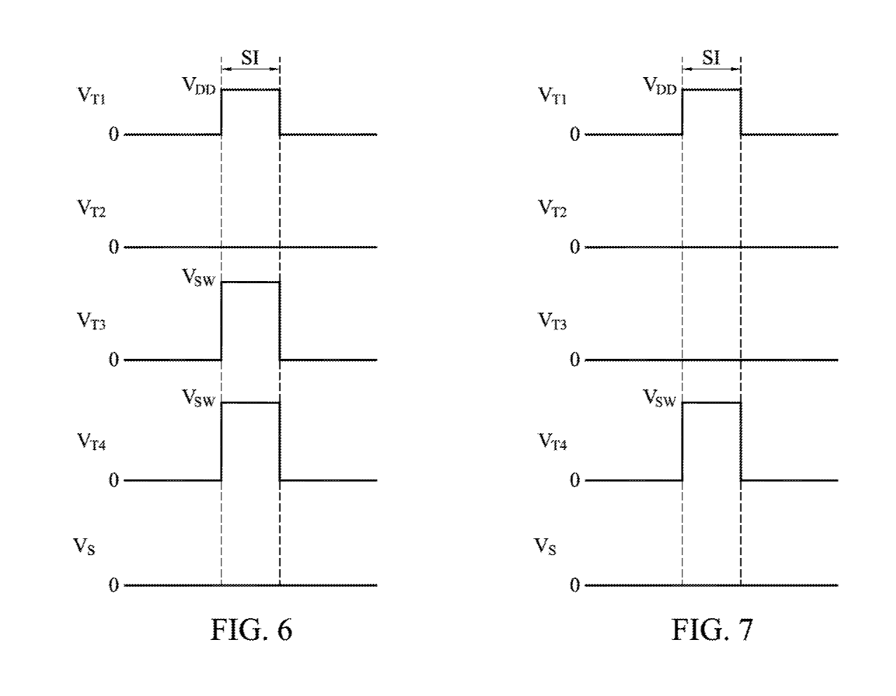

FIG. 6 is a diagram of voltage waveforms applied to the terminals T1, T2, T3, and T4 to change the state of the switch, in accordance with an exemplary embodiment of the present disclosure. In some embodiments, different voltages are used to change the switch from the open (OFF) position to the closed (ON) position; the switching waveforms are valid only within the setting interval. Referring to FIG. 6, the voltage and timing waveforms applied to the terminals T1, T2, T3, and T4 of the non-volatile memory cell 10A illustrated in FIG. 3 force a transition of the switch 20 from a first position, in contact with the first electrode 24 as illustrated in FIG. 4, to a second position, in contact with the second electrode 18 as illustrated in FIG. 5.

The switching waveforms are valid only within the setting interval (SI). A voltage V_{T4}, when applied to the terminal T4, transitions to switching voltage V_{SW}; a voltage V_{T2}, when applied to the terminal T2, has 0 volt; and a voltage V_{T3}, when applied to the terminal T3, transitions to switching voltage V_{SW}. The terminal T1, when electrically coupled to the control node 12, transitions from 0 volt to the voltage V_{DD} to activate the control node 12, generating the channel in the channel region 17 illustrated in FIG. 3, and thereby causing the source voltage V_{S} to be 0 volt. The electrostatic force between the switch 20 in the first position and the first electrode 24 is zero because the voltage difference between the switch 20 and the first electrode 24 is 0 volt. The voltage difference between the V_{T3} and V_{S} is V_{SW}; this voltage difference between the V_{3T} and the V_{S} generates an electrostatic force to cause a transition of the switch 20 from the first position, where the second end 212 of the nanotube 21 is in contact with the first electrode 24 as illustrated in FIG. 4, to the second position, where the second end 212 of the nanotube 21 is in contact with the second electrode 18 as illustrated in FIG. 5. In some embodiments, the switching voltage V_{SW} is about 5 volts and the V_{DD} is about 1.5 volts.

FIG. 7 is another diagram of voltage waveforms applied to the terminals T1, T2, T3, and T4 to change the state of the switch. Referring to FIG. 7, the voltage and timing waveforms applied to the terminals T1 to T4 of the non-volatile memory cell 10A cause a transition of the switch 20 from the second position, where the second end 212 of the nanotube 21 is in contact with the second electrode 18 as illustrated in FIG. 5, to the first position, where the second end 212 of the nanotube 21 is in contact with the first electrode 24 as illustrated in FIG. 4. The switch 20 transitions from the closed (ON) state to the open (OFF) state. The voltage V_{T4}, when applied to the terminal T4, transitions to the voltage V_{SW}; the voltage V_{T2}, when applied to the terminal T2, is 0 volt; and the voltage V_{T3}, when applied to the terminal T3, is 0 volts. The terminal T1, when electrically coupled to the 2s control node 12, transitions from 0 volt to V_{DD} volts, generating the channel in the channel region 17 illustrated in FIG. 3, and thereby reducing the source voltage V_{S} to 0 volt. The voltage difference between the switch 20 in the second position and the second electrode 18 is 0 volt; therefore the electrostatic force between the switch 20 in the second position and the second electrode 18 is substantially 0 newton. The voltage difference between the V_{T4} and the V_{T3} generates an electrostatic force which causes a transition of the switch 20 from the second position, where the second end 212 of the nanotube 21 is in contact with the second electrode 18 as illustrated in FIG. 5, to the first position, where the second end 212 of the nanotube 21 is in contact with the first electrode 24 as illustrated in FIG. 4. In some embodiments, the switching voltage V_{SW} is about 5 volts; and the V_{DD} is 1.5 volts.

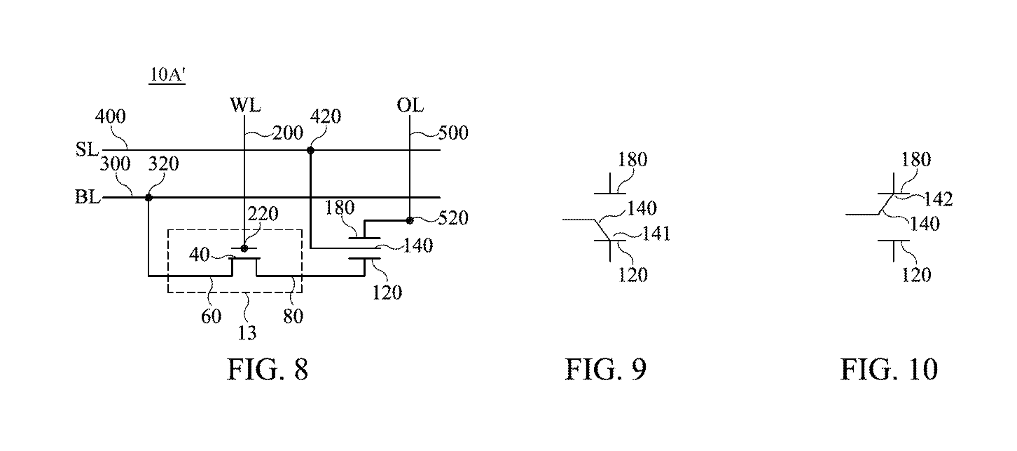

FIG. 8 is a schematic circuit diagram of a non-volatile memory cell 10A′. Referring to FIG. 8, a word line (WL) 200 is electrically coupled to a terminal 220; a bit line (BL) 300 is electrically coupled to a terminal 320; a switch line (SL) 400 is electrically coupled to a terminal 420; and an open line (OL) 500 is electrically coupled to a terminal 520. The non-volatile memory cell 10A′ performs a writing operation, and stores a bit of data in a non-volatile manner. A select device (gate) 40 of the non-volatile memory cell 10A′ corresponds to the control node 12 illustrated in FIG. 3; a drain 60 of the non-volatile memory cell 10A′ corresponds to the first node 14 illustrated in FIG. 3; a source 80 of the non-volatile memory cell 10A′ corresponds to the second node 16 illustrated in FIG. 3; a second electrode 120 corresponds to the second electrode 18 illustrated in FIG. 3; a switch 140 corresponds to the switch 20 illustrated in FIG. 3, and a first electrode 180 corresponds to the first electrode 24 illustrated in FIG. 3. The interaction and operation of the elements of the non-volatile memory cell 10A′ schematically correspond to the interaction and operation of the elements of the non-volatile memory cell 10A. The BL 300 is electrically coupled to the drain 60 of the non-volatile memory cell 10A′ via the terminal 320; the SL 400 is electrically coupled to the switch 140 via the terminal 420; the OL 500 is electrically coupled to the first electrode 180 via the terminal 520; and a WL 200 is electrically coupled to the gate 40 by the terminal 220. The switch 140 is attracted to make contact with the second electrode 120 by electrostatic force to a closed (ON) position 141 for storing a logic 1 as illustrated in FIG. 9; the van der Waals force holds the switch 140 in the position 141 without electrostatic force. Alternatively, the switch 140 is attracted to make contact with the first electrode 180 by electrostatic force to an open (OFF) position 142 for storing a logic 0 as illustrated in FIG. 10; the van der Waals force holds the switch 140 in the position 142 without electrostatic force. Using such mechanism, the non-volatile memory cell 10A′ stores a bit of data in a non-volatile manner.

The non-volatile memory cell 10A′ is switched between a closed state (switched to the position 141 as illustrated in FIG. 9) and an open state (switched to the position 142 as illustrated in FIG. 10). Using the mechanism to store the closed state or the open state, the non-volatile memory cell 10A′ is used as a basis element for forming a non-volatile random access memory.

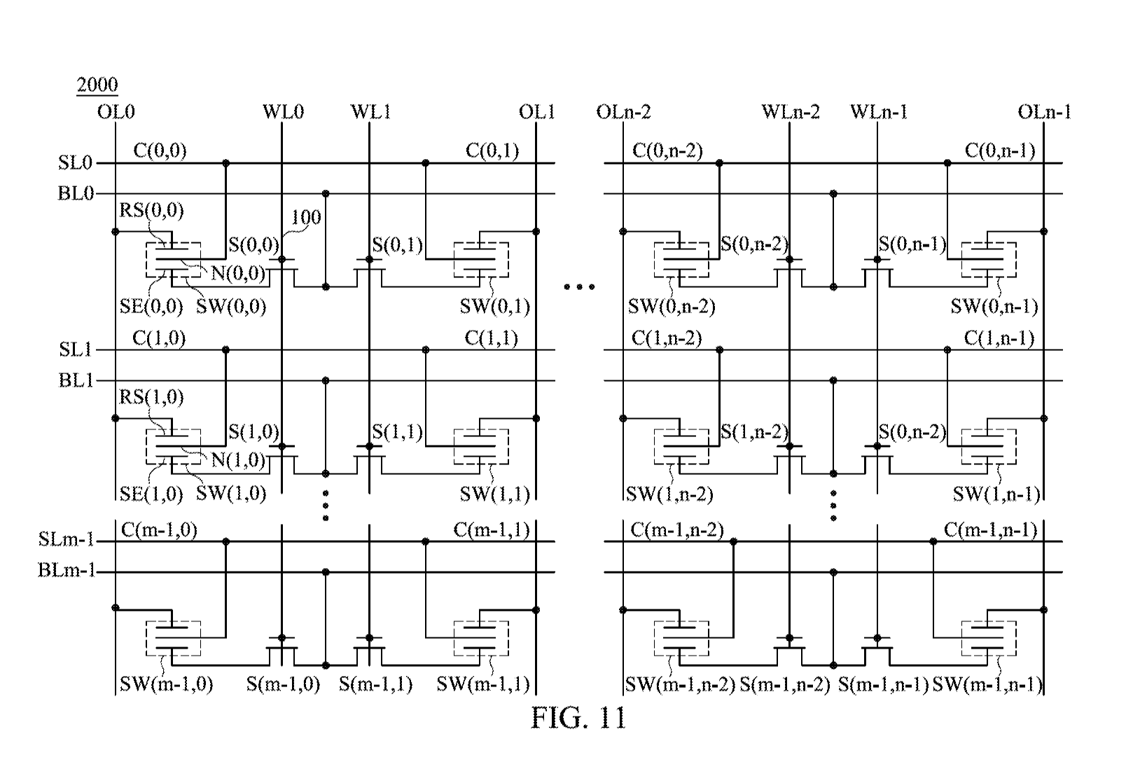

FIG. 11 is a schematic circuit diagram of a non-volatile random access memory 2000, in accordance with an exemplary embodiment of the present disclosure. Referring to FIG. 11, an m×n array is formed with non-volatile memory cells which are similar to the non-volatile memory cell 10A′ illustrated in FIG. 8 and range from a cell C(0,0) to a cell C(m−1, n−1). In order to access a selected cell, the array controls word lines (WL0, WL1, . . . WLn−1), controls bit lines (BL0, BL1, . . . BLm−1), controls switch lines (SL0, SL1, . . . SLm−1), and controls open lines (OL0, OL1, . . . OLn−1). The cell C(0,0) includes a select device S(0,0) and a switch SW(0,0). The gate of S(0,0) is electrically coupled to the WL WL0, and the drain of S(0,0) is coupled to the BL BL0. A switch SW(0,0) includes the second electrode SE(0,0) electrically coupled to the source of S(0,0), the nanotube N(0,0) electrically coupled to the SL SL0, and the first electrode RS(0,0) electrically coupled to the OL OL0. A connection 100 electrically couples the BL BL0 to a shared drain of the select device S(0,0) and a select device S(0,1).

In some embodiments, the nanotube N(0,0) included in the switch SW(0,0) is in the ON (1) state or in the OFF (0) state.

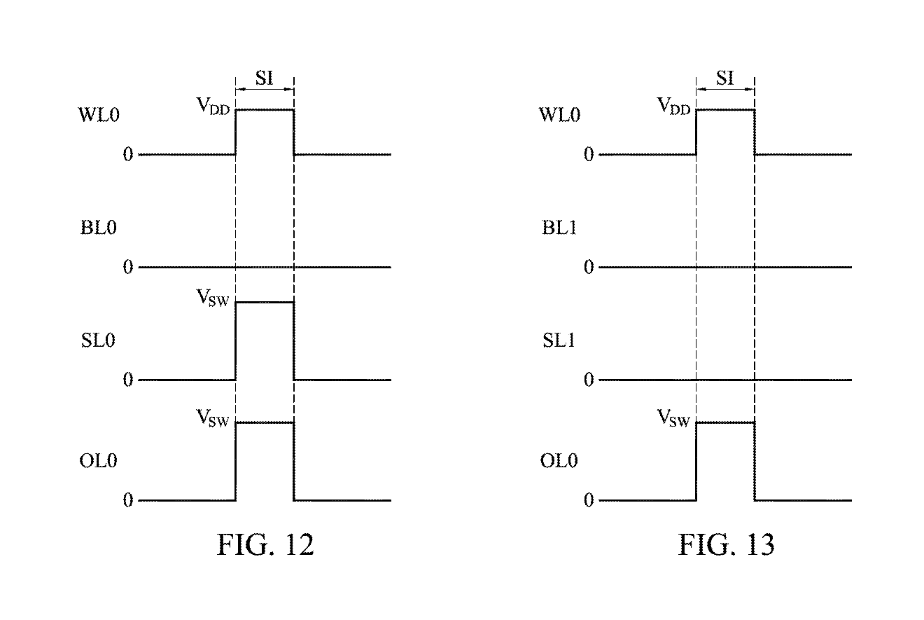

FIG. 12 is a diagram of voltage waveforms applied to the WL WL0, the BL BL0, the SL SL0 and the OL OL0 to change the state of the nanotube N(0,0), in accordance with an exemplary embodiment of the present disclosure. Referring to FIG. 11 and FIG. 12, in some embodiments, for a writing 1 operation to the cell C(0,0), the select device S(0.0) is activated when the WL WL0 transitions from 0 volts to V_{DD} volts, the BL BL0 has 0 volt, the SL SL0 transitions from 0 volt to the switching voltage V_{SW} volts, and the open line OL0 transitions from 0 volt to the switching voltage V_{SW} volts. The first electrode RS(0,0) and the nanotube N(0,0) of the switch SW(0,0) both have voltage of V_{SW} volts resulting in 0 newton of electrostatic force because the voltage difference between the first electrode RS(0,0) and the nanotube N(0,0) is 0 volt. The BL BL0 with 0 volts is applied to the second electrode SE(0,0) of the switch SW(0,0) via the source of select device S(0,0). The voltage difference between the second electrode SE(0,0) and the nanotube N(0,0) is V_{SW} volts and generates an attracting electrostatic force; the second electrode SE(0,0) is attracted to contact the nanotube N(0,0). In some embodiments, V_{SW} exceeds a threshold voltage V_{T}, and the attracting electrostatic force between the second electrode SE(0,0) and the nanotube N(0,0) exceeds the van der Waals force between the first electrode RS(0,0) and the nanotube N(0,0), so the nanotube N(0,0) switches to the ON state or the logic 1 state, that is, the switch 140 and the second electrode 120 are electrically coupled as illustrated in FIG. 9. The electrical connection between the second electrode 120 and the switch 140 in the position 141 represents the ON state or the logic 1 state. Even if the electrical power is lost, the cell C(0,0) still remains in the ON state or the logic 1 state. In some embodiments, the threshold voltage V_{T} is about 5 volts.

FIG. 13 is another diagram of voltage waveforms applied to the WL WL0, a BL BL1, an SL SL1 and the OL OL0, to change a position of the nanotube N(1,0), in accordance with an exemplary embodiment of the present disclosure. Referring to FIG. 11 and FIG. 13, for a writing 0 operation to a cell C(1,0), a select device S(1,0) is activated when the WL WL0 transitions from 0 volts to V_{DD} volts, the BL BL1 has 0 volts, the SL SL1 has 0 volts, and the OL OL0 transitions from 0 volt to V_{SW} volts. The BL BL1 voltage is 0 volt and the BL1 voltage is applied to a second electrode SE(1,0) of a switch SW(1,0) via the source of the select device S(1,0), and 0 volt is applied to the nanotube N(1,0) by the SL SL1, resulting in 0 newton of electrostatic force between the second electrode SE(1,0) and the nanotube N(1,0). The first electrode RS(1,0) having switching voltage V_{SW} volts and the nanotube N(1,0) having 0 volts generate an attracting electrostatic force. If the voltage switching V_{SW} exceeds the threshold voltage V_{T}, the switch SW(1,0) switches to the OFF state or a logic 0 state; that is, the switch 140 and the first electrode 180 are in contact as illustrated in FIG. 10. The electrical connection between the first electrode 180 and the switch 140 in a position 142 represents the OFF state or the logic 0 state. Even if the electrical power is lost, the cell C(1,0) still remains in the OFF state or the logic 0 state. In some embodiments, the threshold voltage V_{T} is about 5 volts.

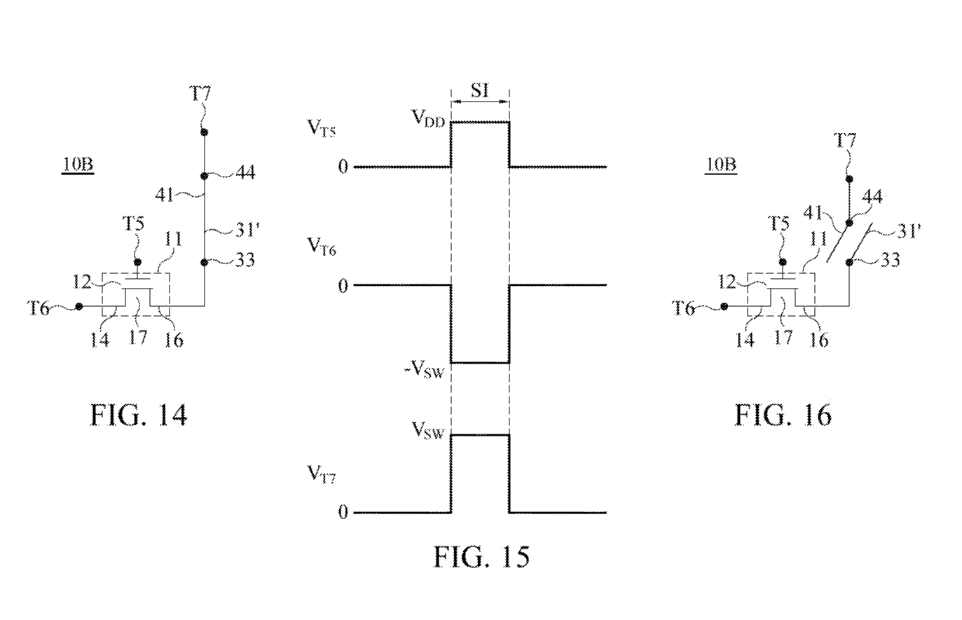

FIG. 14 is an operation diagram of a non-volatile memory cell 10B, in accordance with an exemplary embodiment of the present disclosure. Referring to FIG. 14, the non-volatile memory cell 10B includes the transistor 11, a first contact 44, a first nanotube 41, a second contact 33, a second nanotube 31, a terminal T5, a terminal T6, and a terminal T7. The transistor 11 includes the control node 12, the first node 14 and the second node 16. The second node 16 of the 1U transistor 11 is electrically coupled to the second contact 33, and the second contact 33 is electrically coupled to the second nanotube 31. The terminal T7 is electrically coupled to the first contact 44, and the first contact 44 is electrically coupled to the first nanotube 41.

FIG. 15 is a diagram of voltage waveforms applied to the terminals T5, T6, and T7 for a writing 1 operation, in accordance with an exemplary embodiment of the present disclosure. Referring to FIG. 14 and FIG. 15, a voltage V_{DD} is applied to the terminal T5 in order to activate the channel 17, which is between the first node 14 and the second node 16 of the transistor 11; a voltage −V_{SW} is applied to the terminal T6, so that the second nanotube 31 has the voltage −V_{SW}; and a voltage V_{SW} is applied to the terminal T7. Because the voltage −V_{SW} is applied to the second nanotube 31 and the voltage V_{SW} is applied to the first nanotube 41, the second nanotube 31 and the first nanotube 41 are attracted and contact each other, thereby causing a closed state between the first node 14 of the transistor 11 and the terminal T7, which represents a non-volatile logic 1 state.

FIG. 16 is another operation diagram of the non-volatile memory cell 10B, in accordance with an exemplary embodiment of the present disclosure. Referring to FIG. 16, the terminal T5 is electrically coupled to the control node 12 of the transistor 11, the terminal T6 is electrically coupled to the first node 14 of the transistor 11, the second node 16 of the transistor 11 is electrically coupled to the second contact 33, the second contact 33 is electrically coupled to the second nanotube 31, the terminal T7 is electrically coupled to the first contact 44, and the first contact 44 is electrically coupled to the first nanotube 41.

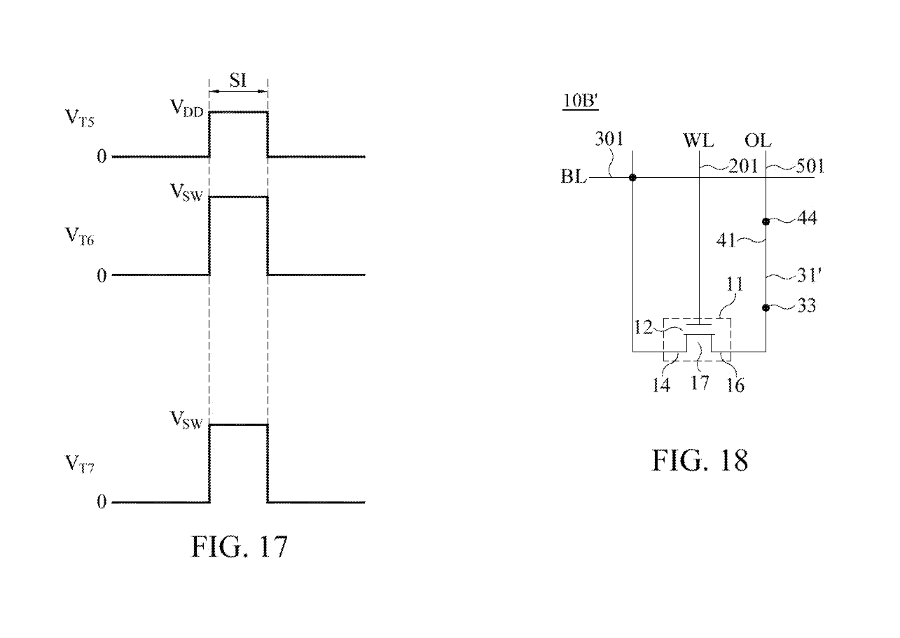

FIG. 17 is a diagram of voltage waveforms applied to the terminals T5, T6, and T7 for a writing 0 operation, in accordance with an exemplary embodiment of the present disclosure. Referring to FIG. 16 and FIG. 17, a voltage V_{DD} is applied to the terminal T5 in order to activate the channel 17, which is between the first node 14 of the transistor 11 and the second node 16 of the transistor 11; a voltage V_{SW} is applied to the terminal T6, so that the second nanotube 31 has a voltage V_{SW}. A voltage V_{SW} is applied to a terminal T7. Therefore, because the same voltage, V_{SW}, is applied to both the second nanotube 31 and the first nanotube 41, the second nanotube 31 and the first nanotube 41 repel each other, thereby causing an open state between the first node 14 of the transistor 11 and the terminal T7, which represents a non-volatile logic 0 state.

FIG. 18 is an operation diagram of a non-volatile memory cell 10B′ in accordance with an exemplary embodiment of the present disclosure. Referring to FIG. 18, a WL 201 is electrically coupled to the control node 12 of the transistor 11, a BL 301 is electrically coupled to the first node 14 of the transistor 11, the second node 16 of the transistor 11 is electrically coupled to the second contact 33, the second contact 33 is electrically coupled to the second nanotube 31, an OL 501 is electrically coupled to the first contact 44, and the first contact 44 is electrically coupled to the first nanotube 41.

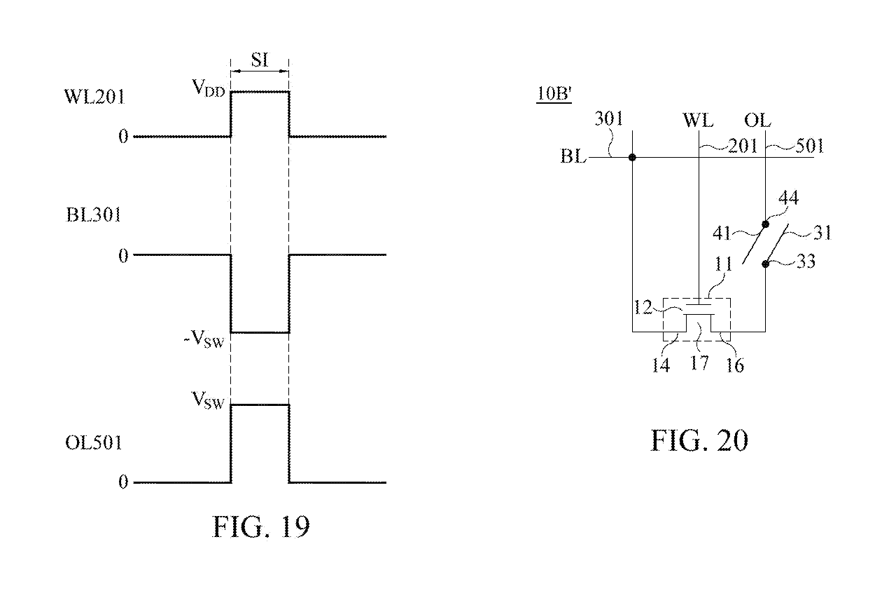

FIG. 19 is a diagram of voltage waveforms applied to the WL 201, the BL 301 and the OL 501 for a writing 1 operation, in accordance with an exemplary embodiment of the present disclosure. Referring to FIG. 18 and FIG. 19, within the setting interval SI, a voltage V_{DD} is applied to the WL 201 in order to activate the channel 17, while a voltage −V_{SW} is applied to the BL 301, thereby causing the second nanotube 31 to have a voltage −V_{SW}. A voltage V_{SW} is applied to the OL 501. Because the voltage −V_{SW} is applied to the second nanotube 31 and the voltage V_{SW} is applied to the first nanotube 41, the second nanotube 31 and the first nanotube 41 are attracted and contact each other, thereby causing a closed state between the BL 301 and the OL 501, which represents a non-volatile logic 1 state.

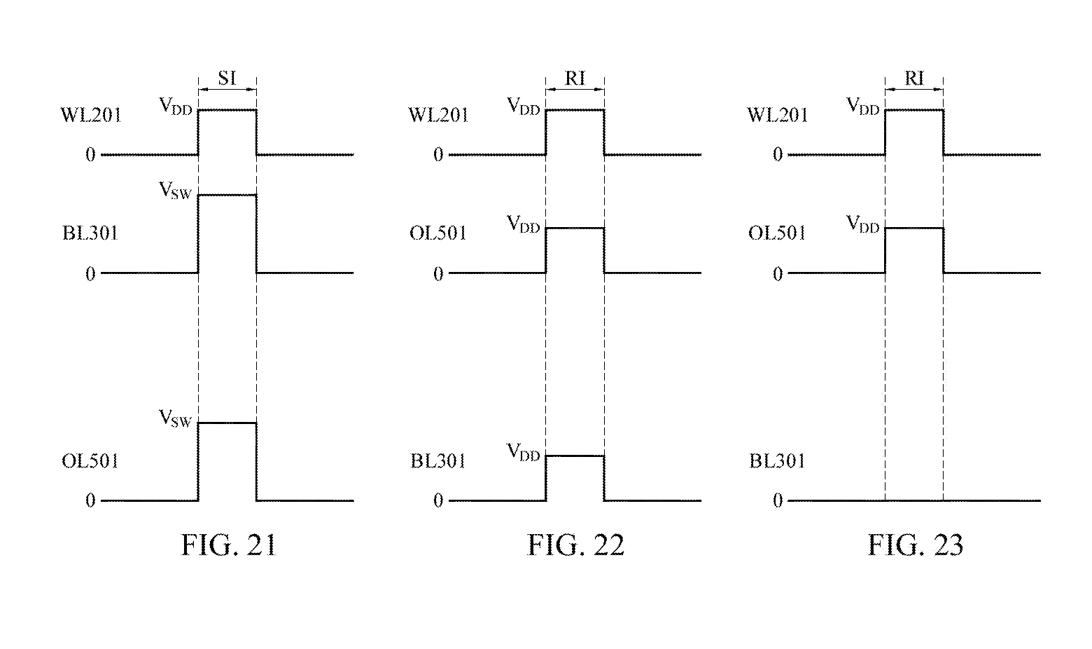

FIG. 20 is an operation diagram of the non-volatile memory cell 10B′, in accordance with an exemplary embodiment of the present disclosure. FIG. 21 is a diagram of voltage waveforms applied to the WL line 201, the BL 301 and the OL 501 for a writing 0 operation, in accordance with an exemplary embodiment of the present disclosure. Referring to FIG. 20 and FIG. 21, within the setting interval SI, a voltage V_{DD} is applied to the WL 201 in order to activate the channel 17, and a voltage V_{SW} is applied to the BL 301, causing the second nanotube 31 to have a voltage V_{SW}. A voltage V_{SW} is applied to the OL 501. Because a voltage V_{SW} is applied to the second nanotube 31, and the same voltage V_{SW} is applied to the first nanotube 41, the second nanotube 31 and the first nanotube 41 repel each other, thereby causing an open state between the BL 301 and the OL 501, which represents a non-volatile logic 0 state.

FIG. 22 is a diagram of voltage waveforms applied to the WL 201 and the OL 501 within the reading interval RI for reading the voltage of the BL 301, in accordance with an exemplary embodiment of the present disclosure. Referring to FIG. 18 and FIG. 22, within the reading interval RI, a voltage V_{DD} is applied to the WL 201, and a voltage V_{DD} is applied to the OL 501. Because the second nanotube 31 and the first nanotube 41 are electrically coupled, the voltage V_{DD} is applied to the BL 301 by the OL 501, and the BL 301 has the voltage V_{DD} within the reading interval RI, which represents a non-volatile logic 1 state.

FIG. 23 is another diagram of voltage waveforms applied to the WL 201 and the OL 501 within the reading interval RI for reading the voltage of the BL 201, in accordance with an exemplary embodiment of the present disclosure. Referring to FIG. 20 and FIG. 23, within the reading interval RI, a voltage V_{DD} is applied to the WL 201, and a voltage V_{DD} is applied to the OL 501. Because the second nanotube 31 and the first nanotube 41 are not electrically coupled, a voltage VD is not applied to the BL 201 by the OL 501, and therefore the BL 301 has the voltage of 0 volt within the reading interval RI, which represents a logic 0 state.

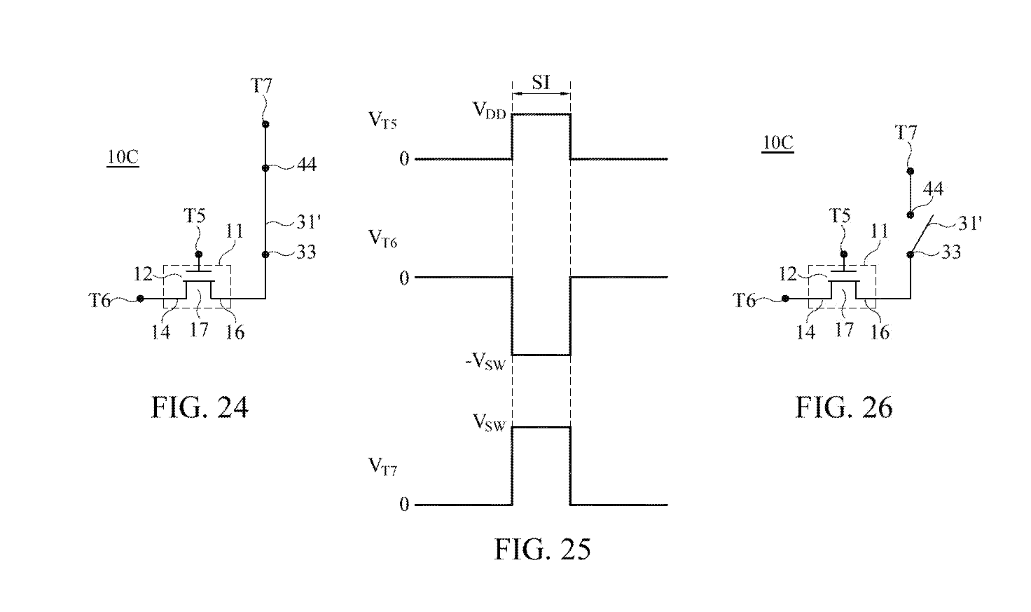

FIG. 24 is an operation diagram of a non-volatile memory cell 10C, in accordance with an exemplary embodiment of the present disclosure. Referring to FIG. 24, the non-volatile memory cell 10C includes the transistor 11, the first contact 44, the second contact 33, a nanotube 31′, the terminal T5, the terminal T6, and the terminal T7. The transistor 11 includes the control node 12, the first node 14 and the second node 16. The second node 16 of the transistor 11 is electrically coupled to the second contact 33, and the second contact 33 is electrically coupled to the nanotube 31′. The terminal T7 is electrically coupled to the first contact 44.

FIG. 25 is a diagram of voltage waveforms applied to the terminals T5, T6, and T7 for a writing 1 operation, in accordance with an exemplary embodiment of the present disclosure. Referring to FIG. 24 and FIG. 25, a voltage V_{DD} is applied to the terminal T5 in order to activate the channel 17, which is between the first node 14 of the transistor 11 and the second node 16 of the transistor 11; a voltage −V_{SW} is applied to the terminal T6, so that the nanotube 31′ has the voltage −V_{SW}; and a voltage V_{SW} is applied to the terminal T7. Because the voltage −V_{SW} is applied to the nanotube 31′ and the voltage V_{SW} is applied to the first nanotube 41, the nanotube 31′ and the first contact 44 are attracted and contact each other, thereby causing a closed state between the first node 14 of the transistor 11 and the terminal T7, which represents a non-volatile logic 1 state.

FIG. 26 is another operation diagram of the non-volatile memory cell 10C, in accordance with an exemplary embodiment of the present disclosure. Referring to FIG. 26, the terminal T5 is electrically coupled to the control node 12 of the transistor 11, the terminal T6 is electrically coupled to the first node 14 of the transistor 11, the second node 16 of the transistor 11 is electrically coupled to the second contact 33, the second contact 33 is electrically coupled to one end of the nanotube 31′, the terminal T7 is electrically coupled to the first contact 44.

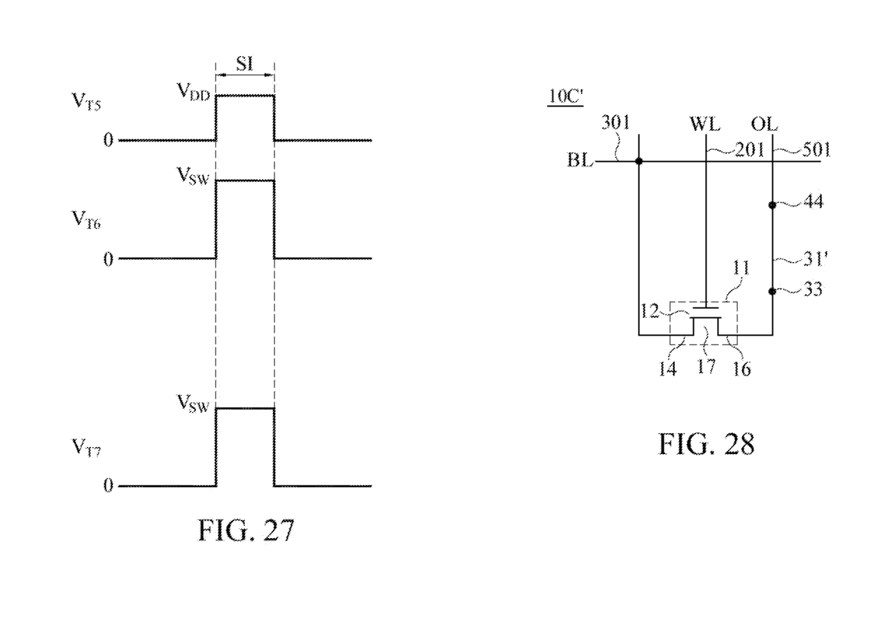

FIG. 27 is a diagram of voltage waveforms applied to the terminals T5, T6, and T7 for a writing 0 operation, in accordance with an exemplary embodiment of the present disclosure. Referring to FIG. 26 and FIG. 27, a voltage V_{DD} is applied to the terminal T5 in order to activate the channel 17, which is between the first node 14 and the second node 16 of the transistor 11; a voltage V_{SW} is applied to the terminal T6, so that the nanotube 31′ has a voltage V_{SW}. A voltage V_{SW} is applied to a terminal T7. Therefore, because the same voltage, V_{SW}, is applied to both the nanotube 31′ and the first contact 44, the nanotube 31′ and the first contact 44 repel each other, thereby causing an open state between the first node 14 of the transistor 11 and the terminal T7, which represents a non-volatile logic 0 state.

FIG. 28 is an operation diagram of a non-volatile memory cell 10C′ in accordance with an exemplary embodiment of the present disclosure. Referring to FIG. 28, the WL 201 is electrically coupled to the control node 12 of the transistor 11, the BL 301 is electrically coupled to the first node 14 of the transistor 11, the second node 16 of the transistor 11 is electrically coupled to the second contact 33, the second contact 33 is electrically coupled to the nanotube 31′, the OL 501 is electrically coupled to the first contact 44.

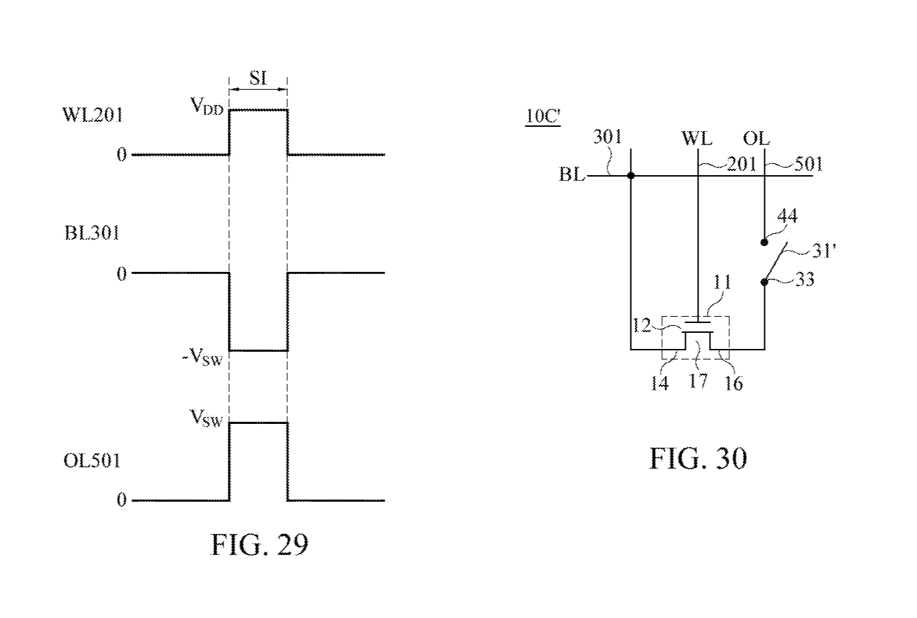

FIG. 29 is a diagram of voltage waveforms applied to the WL 201, the BL 301 and the OL 501 for a writing 1 operation, in accordance with an exemplary embodiment of the present disclosure. Referring to FIG. 28 and FIG. 29, within the setting interval SI, a voltage V_{DD} is applied to the WL 201 in order to activate the channel 17, while a voltage −V_{SW} is applied to the BL 301, thereby causing the nanotube 31′ to have a voltage −V_{SW}. A voltage V_{SW} is applied to the OL 501. Because the voltage −V_{SW} is applied to the nanotube 31′ and the voltage V_{SW} is applied to the first contact 44, the nanotube 31′ and the first contact 44 are attracted and contact each other, thereby causing a closed state between the BL 301 and the OL 501, which represents a non-volatile logic 1 state.

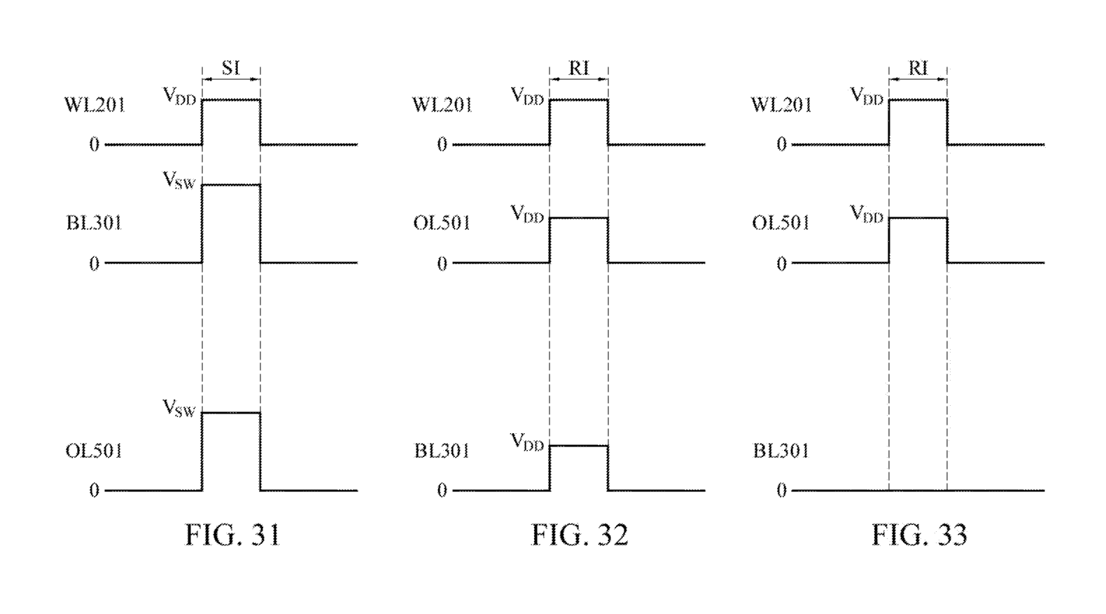

FIG. 30 is an operation diagram of a non-volatile memory cell 10C′, in accordance with an exemplary embodiment of the present disclosure. FIG. 31 is a diagram of voltage waveforms applied to the WL line 201, the BL 301 and the OL 501 for a writing 0 operation, in accordance with an exemplary embodiment of the present disclosure. Referring to FIG. 30 and FIG. 31, within the setting interval SI, a voltage V_{DD} is applied to the WL 201 in order to activate the channel 17, and a voltage V_{SW} is applied to the BL 301, causing the nanotube 31′ to have a voltage V_{SW}. A voltage V_{SW} is applied to the OL 501. Because a voltage V_{SW} is applied to the nanotube 31′, and the same voltage V_{SW} is applied to the first contact 44, the nanotube 31′ and the first contact 44 repel each other, thereby causing an open state between the BL 301 and the OL 501, which represents a non-volatile logic 0 state.

FIG. 32 is a diagram of voltage waveforms applied to the WL 201 and the OL 501 within the reading interval (RI) for reading the voltage of the BL 301, in accordance with an exemplary embodiment of the present disclosure. Referring to FIG. 28 and FIG. 32, within the reading interval RI, a voltage V_{DD} is applied to the WL 201, and a voltage V_{DD} is applied to the OL 501. Because the nanotube 31′ and the first nanotube 41 are electrically coupled, the voltage V_{DD} is applied to the BL 301 by the OL 501, and the BL 301 has the voltage V_{DD} within the reading interval RI, which represents a logic 1 state.

FIG. 33 is another diagram of voltage waveforms applied to the WL 201 and the OL 501 within the reading interval RI for reading the voltage of the BL 201, in accordance with an exemplary embodiment of the present disclosure. Referring to FIG. 30 and FIG. 33, within the reading interval RI, a voltage V_{DD} is applied to the WL 201, and a voltage V_{DD} is applied to the OL 501. Because the nanotube 31′ and the first contact 44 are not electrically coupled, a voltage V_{DD} is not applied to the BL 201 by the OL 501, and therefore the BL 301 has the voltage of 0 volt within the reading interval RI, which represents a logic 0 state.

In the present disclosure, when the applied voltage difference between the nanotube and a reference electrode exceeds a threshold voltage difference, the switch 20 changes the equilibrium position of the switch 20. The reference electrode includes the second electrode 18 and the first electrode 24. Once the switch 20 is in contact with the reference electrode, the electrostatic force is removed by reducing the voltage difference between the switch 20 and the reference electrode to 0 volts. Even if the electrical power is lost, the switch 20 still remains in stable contact with the first electrode 24 as illustrated in FIG. 4, or still remains in stable contact with the second electrode 18 as illustrated in FIG. 5, and thus stores a bit of data in a non-volatile manner. Another advantage is that the switch 20 does not need to consume any electrical power if the switch 20 does not change its state or write data.

In contrast, the DRAM stores each bit of data in a separate capacitor within an integrated circuit. The electric charge in the capacitors slowly leaks off, so without intervention the DRAM will lose the data quickly; therefore the DRAM cannot store data in a non-volatile manner. Another disadvantage is that the DRAM still consumes electrical power even if the DRAM does not change the data.

One aspect of the present disclosure provides a memory device comprising a first electrode, a second electrode, a transistor and a nanotube. The transistor comprises a first node, a second node and a control node, wherein the second node is electrically coupled to the second electrode, and the control node is configured to generate a channel between the first node and the second node. A first end of the nanotube is electrically coupled to a contact, and a second end of the nanotube is positioned between the first electrode and the second electrode; wherein the second end electrically connects the first electrode to form a non-volatile open state of the memory device, or the second end electrically connects the second electrode to form a non-volatile closed state of the memory device; wherein the non-volatile open state represents a first logic state and the non-volatile closed state represents a second logic state.

Another aspect of the present disclosure provides a memory device comprising a first contact, a second contact, a first nanotube electrically coupled to the first contact, a second nanotube electrically coupled to the second contact, and a transistor. The transistor comprises a first node, a second node and a control node, wherein the second node is electrically coupled to the second contact, and the control node is configured to activate a channel between the first node and the second node. The first nanotube electrically connects the second nanotube to form a non-volatile closed state of the memory device, or electrically disconnects the second nanotube to form a non-volatile open state of the memory device, wherein the non-volatile closed state represents a first logic state and the non-volatile open state represents a second logic state.

Another aspect of the present disclosure provides a memory device comprising a first contact, a second contact, a transistor and a nanotube. The transistor comprises a first node, a second node and a control node, wherein the second node is electrically coupled to the second contact, and the control node is configured to activate a channel between the first node and the second node. The nanotube electrically connects the first contact and the second contact to form a non-volatile closed state of the memory device, or electrically disconnects the first contact and the second contact to form a non-volatile open state of the memory device, wherein the non-volatile closed state represents a first logic state and the non-volatile open state represents a second logic state.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A memory device, comprising:
a first electrode;
a second electrode;
a transistor having a first node, a second node and a control node, wherein the second node is electrically coupled to the second electrode, and the control node is configured to generate a channel between the first node and the second node; and
a nanotube, wherein a first end of the nanotube is electrically coupled to a contact, and a second end of the nanotube is positioned between the first electrode and the second electrode, wherein the second end electrically connects the first electrode to form a non-volatile open state of the memory device, or the second end electrically connects the second electrode to form a non-volatile closed state of the memory device, wherein the non-volatile open state represents a first logic state and the non-volatile closed state represents a second logic state.

2. The memory device of claim 1, wherein a first voltage applied to the contact, and the second end of the nanotube is attracted by the second electrode, to which a second voltage is applied, when the memory device is under the non-volatile closed state; wherein the first voltage is substantially different from the second voltage.

3. The memory device of claim 1, wherein a third voltage applied to the contact, the second end of the nanotube is attracted by the first electrode, to which a fourth voltage is applied, when the memory device is under the non-volatile open state; wherein the third voltage is substantially the same as the fourth voltage.

4. The memory device of claim 1, wherein the nanotube is a carbon nanotube doped with nitrogen.

5. The memory device of claim 4, wherein the nitrogen concentration of the carbon nanotube doped with nitrogen is between 2% and 10%.

6. The memory device of claim 1, wherein the non-volatile open state is formed between the second node and the contact, and the non-volatile closed state is formed between the second node and the contact.

7. The memory device of claim 1, wherein the control node is activated to generate the channel between the first node and the second node, the non-volatile open state is formed between the first node and the contact, and the non-volatile closed state is formed between the first node and the contact.

8. A memory device comprising:
a first contact;
a second contact;
a first nanotube electrically coupled to the first contact;
a second nanotube electrically coupled to the second contact;
a transistor having a first node, a second node and a control node, wherein the second node is electrically coupled to the second contact, and the control node is configured to activate a channel between the first node and the second node; and
wherein the first nanotube electrically connects the second nanotube to form a non-volatile closed state of the memory device, or electrically disconnects the second nanotube to form a non-volatile open state of the memory device, wherein the non-volatile closed state represents a first logic state and the non-volatile open state represents a second logic state.

9. The memory device of claim 8, wherein a first voltage applied to the first contact, the first nanotube is attracted by the second nanotube, to which a second voltage is applied when the memory device is under the non-volatile closed state; wherein the first voltage is substantially different from the second voltage.

10. The memory device of claim 8, wherein a third voltage applied to the first contact, the first nanotube is repelled by the second nanotube, to which a fourth voltage is applied when the memory device is under the non-volatile open state; wherein the third voltage is substantially the same as the fourth voltage.

11. The memory device of claim 8, wherein the first nanotube and the second nanotube are carbon nanotubes doped with nitrogen.

12. The memory device of claim 11, wherein the nitrogen concentration of the carbon nanotubes doped with nitrogen is between 2% and 10%.

13. The memory device of claim 6, wherein the non-volatile open state is formed between the second node and the first contact, and the non-volatile closed state is formed between the second node and the first contact.

14. The memory device of claim 6, wherein the control node is activated to generate the channel between the first node and the second node, the non-volatile open state is formed between the first node and the first contact, and the non-volatile closed state is formed between the first node and the first contact.

15. A memory device comprising:
a first contact;
a second contact;
a transistor having a first node, a second node and a control node, wherein the second node is electrically coupled to the second contact, and the control node is configured to activate a channel between the first node and the second node; and
a nanotube, wherein the nanotube electrically connects the first contact and the second contact to form a non-volatile closed state of the memory device, or electrically disconnects the first contact and the second contact to form a non-volatile open state of the memory device, wherein the non-volatile closed state represents a first logic state and the non-volatile open state represents a second logic state.

16. The memory device of claim 15, wherein a first voltage applied to the first contact and a second voltage is applied to the nanotube, and the nanotube electrically connects the first contact and the second contact when the memory device is under the non-volatile closed state; wherein the first voltage is substantially different from the second voltage.

17. The memory device of claim 15, wherein a third voltage applied to the first contact, a fourth voltage is applied to the nanotube, and the nanotube electrically disconnects the first contact and the second contact when the memory device is under the non-volatile open state; wherein the third voltage is substantially the same as the fourth voltage.

18. The memory device of claim 15, wherein the nanotube is carbon nanotubes doped with nitrogen.

19. The memory device of claim 18, wherein the nitrogen concentration of the carbon nanotube doped with nitrogen is between 2% and 10%.

20. The memory device of claim 15, wherein the nanotube is electrically coupled to the second contact, the non-volatile open state is formed between the second node and the first contact, and the non-volatile closed state is formed between the second node and the first contact.

21. The memory device of claim 15, wherein the nanotube is electrically coupled to the second contact, the control node is activated to generate the channel between the first node and the second node, the non-volatile open state is formed between the first node and the first contact, and the non-volatile closed state is formed between the first node and the first contact.
